(19) United States
(12) Patent Application Publication
(10) Pub. No.: US 2021/0151981 A1
(43) Pub. Date: May 20, 2021

(54) Power Overload Management System for Network Data Centers

(71) Applicant: Edwin Travis Irons, Reno, NV (US)

(72) Inventor: Edwin Travis Irons, Reno, NV (US)

(21) Appl. No.: 16/984,825

(22) Filed: Aug. 4, 2020

Related U.S. Application Data
(60) Provisional application No. 62/974,161, filed on Nov. 18, 2019.

(51) Int. Cl. H02H 7/20; H02H 1/00; H05K 7/14; G06F 1/28; G06F 1/30

(52) U.S. Cl. CPC H02H 7/20; H02H 1/0007; G06F 1/305; G06F 1/28; H05K 7/1492

(57) ABSTRACT

In a network data center, systems and methods which reduce the number and duration of power interruption events resulting from over-current and short-circuit conditions are disclosed. The systems and methods shift loads between electrical phases effectively balancing the utilization of phases, as well as pre-empting circuit breaker and fuse trips through intelligent monitoring and remote control.

### CROSS-REFERENCE TO RELATED APPLICATIONS

This application claims priority to U.S. Provisional Patent Application No. 62/974,161, filed Nov. 18, 2019, the contents of which are incorporated by reference in their entirety.

### TECHNICAL FIELD

The present disclosure is directed to internet data centers, and in certain more particular applications, to the power distribution, power monitoring systems, and circuit protection architecture within.

### BACKGROUND

Data centers are the central component of the internet, places where computers, networking, and telecommunications equipment are housed and maintained. Typical data centers contain numerous racks of computational equipment that require power, cooling, and connections to communications facilities. The equipment racks are typically arranged in rows separated by aisles that allow human access to the front and rear of the racks for installation, configuration, and service of the computational equipment housed within. It is desirable that the computational equipment in the data centers operates seven days a week, 24 hours per day, with little or no disruption of service. One component to achieving this goal is preventing power overloads that result in fault protection devices activating and interrupting power to the equipment.

It is common that alternating three-phase power is distributed throughout the data center to each rack in a three-phase delta or three-phase wye configuration. It is common that there is power distribution equipment at each rack that distributes the three-phase power to single-phase power. It is common that the computational equipment in the rack requires single phase alternating current power to operate.

It is desirable to utilize the three phases of power from the utility as equally as possible, often referred to as phase balancing. Utilizing the three phases equally results in the most efficient usage of power, as it reduces current in the neutral wire of a three-phase wye system and allows for maximum utilization of the available power in a three-phase delta system, among other benefits. Situations where the phases are not utilized equally such that all of the available power can be utilized are often referred to as stranded capacity.

A common method of distributing three-phase power to a plurality of racks oriented in a linear row is by using a plurality of electrical conductors running parallel and in close proximity to the linearly oriented row of racks. It is common that the parallel electrical conductors originate from a distribution panel near the end of each row of racks. At each rack, one or more power distribution devices connects to the parallel electrical conductors and distributes the three-phase power to single phases or single-phase pairs for delivery to the computational equipment.

Phase balancing is accomplished in a data center by manually connecting the computational equipment to the three phases or phase pairs as equally as possible. This method is not ideal, as the power draw from the computational equipment varies over a 24-hour period in response to demand. Additionally, computational equipment is added, removed, and changed on a daily basis within a data center, which introduces challenges in keeping the phases equally utilized, as the newer equipment may have different power usage characteristics.

In the power path from the distribution panel at the end of a row of racks to the computational equipment in the rack, there are a plurality of circuit protection devices, typically circuit breakers or fuses. It is common that a plurality of computational equipment units is connected to a single circuit protection device.

When a circuit protection device activates, or opens, due to an over current condition, it is often referred to as tripped circuit. A tripped circuit interrupts the flow of power.

Circuit protection devices exist in an electrical system in order to prevent damage to the equipment and increase the safety for humans working on or in proximity to the electrical equipment.

A common cause for a circuit protection device to activate is an excess amount of current being drawn by the computational equipment in the rack due to an increasingly high demand of work being placed on the computational equipment.

Another common cause for a circuit protection device to activate is a short duration surge of current due to a fault in the computational equipment creating a short circuit condition. It is common for a short circuit fault within the computational equipment to activate internal circuit protection devices, usually fuses, that interrupt the fault. In the case where fuses internal to the computational equipment open, the computational equipment will no longer operate, nor will it cause a short circuit condition.

The typical fuse-type circuit protection device used in data center power distribution equipment is not resettable, so must be replaced by a human in the event it activates or trips.

The typical circuit breaker-type circuit protection devices used in a data center is not remotely resettable, so must be reset by a human in the event it activates or trips.

As it is desirable to keep the computational equipment running 24 hours, seven days a week, a circuit protection activation event, commonly referred to as a tripped circuit, is undesirable because it requires a human to locate the tripped device and correct it by replacing a fuse or resetting a circuit breaker.

### BRIEF SUMMARY

Embodiments of the invention described herein reduce the occurrences of a power interruption due to over-current and short-circuit conditions and provide for automatic phase balancing of the data center.

In one embodiment, the system monitors the total current being utilized in a plurality of racks, often oriented in a row, connected to a common distribution point, often placed near the end of the row. The system also monitors the current flowing on each branch circuit that supplies power to the computational equipment in the equipment rack. The system has the ability to switch the current being delivered to the equipment between phases or phase pairs for purposes of balancing the utilization from each phase and preventing overloads. The system has the ability to interrupt the current being delivered to the equipment in the rack. The system has the ability to detect if the equipment in the rack is short circuited due to an internal fault.

The system monitors the usage on each phase and selectively switches loads between phases to achieve phase balancing. The phase balancing system may be configured to automatically switch phases to achieve balance, or it may be configured to send a notification to a data center operator who can remotely switch phases.

If the system detects an over-current condition approaching on one of the phases or phase pairs being delivered to a plurality of racks connected to a common distribution point, it selectively switches one or more circuits at one or more of the rack distribution points, from the overloaded phase or phase pair to a less utilized phase or phase pair.

If the system detects an imminent overcurrent condition at the delivery point to the computational equipment that could potentially activate a circuit protection device, commonly a circuit breaker or fuse, it interrupts the current by means of opening a relay or switch prior to the circuit protection device activating. After interrupting the current, the system notifies data center operators or systems of the event. Restoring power to the equipment can then be remotely activated when the demand on the equipment has been reduced such that it would not draw an excess amount of current and cause the circuit protection device to activate.

If the system detects a short duration surge of current that could potentially activate a circuit protection device at the rack distribution point, it interrupts the current by means of opening a relay or switch prior to the circuit protection device activating. It then periodically checks if there is a short circuit in the computational equipment by means of an ohm meter. If it does not detect a short circuit, it automatically restores power by closing the relay. As there is typically more than one computational device on each circuit, those computational devices that are operable are able to return to service.

The topology of the system is such that it minimizes the space consumed in the data center equipment rack. Traditional power distribution equipment, often referred to as intelligent power strips or power distribution units, typically sit inside the equipment rack. The space that is consumed by traditional power strips reduces airflow needed for cooling the computational equipment, and often impedes removal and replacement of the computational equipment or the modular components within the computational equipment such as power supplies and network interface cards.

The topology of the system places the majority of components of the power distribution unit outside of the rack, thus allowing the deployment of a smaller rack. This reduces the footprint of the rack and allows for more racks to fit in a given space, thus increasing the computational power and efficiency of the data center.

Traditional intelligent power strips each contain an independent control system, user interface, and AC to DC power supply. These components occupy a significant volume and add cost to the device. The topology of system has a centralized redundant power supply system and a centralized redundant control system able to power many tens of racks, significantly reducing the total system cost compared to traditional system topologies.

Another aspect of the invention relates to methods for performing the functions described above.

Other aspects, features, and advantages of the invention will be set forth in the description that follows.

### BRIEF DESCRIPTION OF THE DRAWING FIGURES

The invention will be described with respect to the following drawing figures, in which like numerals represent like features throughout the description, and in which:

FIG. 1 is a schematic illustration of an equipment rack in a data center, shown as connected to a power overload control system according to an embodiment of the invention;

FIG. 2 is a schematic illustration of two rows of data center equipment racks, showing how the system of FIG. 1 is connected to each;

FIG. 3 is a schematic illustration similar to the view of FIG. 1, with a more detailed diagram of the components of the system of FIG. 1;

FIG. 4 is a detailed schematic illustration showing the connections of the system with the monitoring and control components;

FIG. 5 is an illustration of an alternate embodiment in which three-phase delta power is distributed into single-phase pairs for delivery into the rack;

FIG. 6 is a flow diagram of a method for using the system of FIG. 1 to automatically manage phase balancing;

FIG. 7 is a flow diagram of a method for using the system of FIG. 1 to manage over-current conditions on the electrical branch circuits in the equipment rack;

FIG. 8 is a flow diagram of a method for using the system of FIG. 1 to manage short-circuit conditions on the electrical branch circuits in the equipment rack;

FIG. 9 is an illustration similar to FIG. 2 showing the use of a system according to an embodiment of the invention with a central controller; and

FIG. 10 is an illustration of a circuit allowing a single phase to be temporarily connected to a highly capacitive or inductive load in order to shift the phase toward the phase that the computational equipment will eventually be shifted to, in order to minimize arcing within the phase-selecting switch or relay.

### DETAILED DESCRIPTION

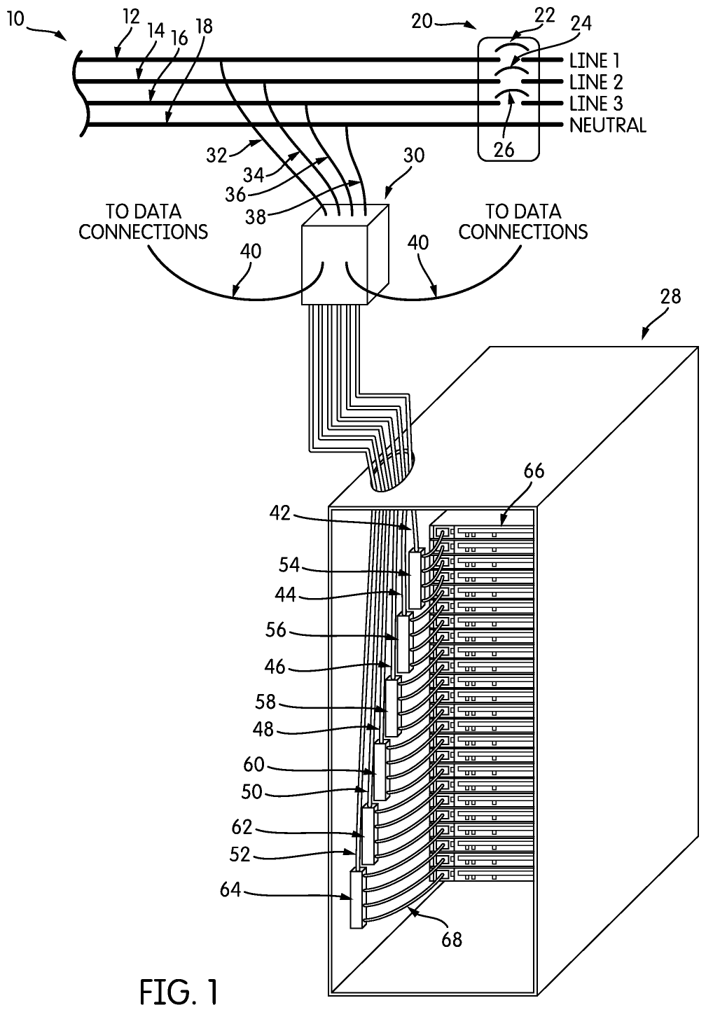

FIG. 1 illustrates a power delivery system, generally indicated at 10, according to one embodiment of the invention. In power delivery system 10, power delivery bus lines 12, 14, 16, 18 are the power delivery bus lines for a three-phase wye electrical system and have the capacity to supply a plurality of equipment racks containing a plurality of computational devices. An end-of-row distribution point 20 contains circuit protection devices 22, 24, and 26, one on each of the three phase lines 12, 14, 16. (The neutral line 18 has no circuit protection device of its own.) An equipment rack 28 is connected to the power delivery bus lines 12, 14, 16, 18 through a power overload control system, which is generally indicated at 30.

More specifically, power is delivered from the power delivery bus lines 12, 14, 16, 18 via connecting cables 32, 34, 36, 38, to the power overload control system 30, which is shown as a single module in the view of FIG. 1, although, as will be described below, it may take the form of multiple, interconnected modules. System module 30 receives data and power for its local control system through connection cables 40, although these could be wireless or optical interconnections, for example, that are not physically visible. Single phase power is delivered into the rack 28 by interconnecting cables 42, 44, 46, 48, 50, 52 to outlet strips 54, 56, 58, 60, 62, 64. Single phase power is delivered to the computational equipment 66 by interconnecting cables 68.

Although FIG. 1 shows the system module 30 distributing six lines of power 42, 44, 46, 48, 50, 52, commonly referred to as branch circuits, into the rack 28, this is for illustration only, as the number of branch circuits can vary depending on the application, and would typically increase as the total potential power requirement of the computational equipment 66 increases. Additionally, although FIG. 1 shows the six outlet strips 54, 56, 58, 60, 62, 64 within the rack having four outlets each, it should be noted that the number of outlets in each outlet strip can vary by number and type depending on the requirements of the computational equipment.

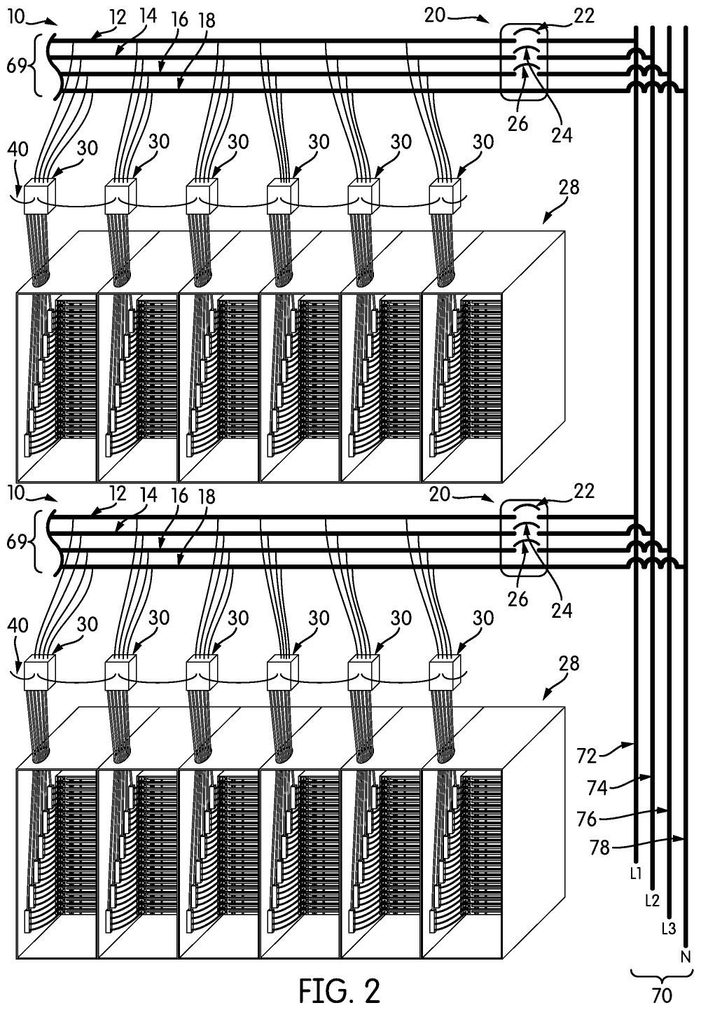

FIG. 2 illustrates two rows of data center equipment racks 28. Each row of equipment racks is supplied power from a three-phase wye electrical busway 69 with lines 12, 14, 16, 18, that is in turn connected to a higher-capacity bus way 70 with lines 72, 74, 76, 78 shown running perpendicular to the rows of equipment racks. Circuit protection devices 22, 24 26 lie at the intersection between the two bus ways 69, 70. System modules 30 are connected between each of the smaller bus ways 69 and the equipment racks 28. Each system module 30 is interconnected by a data communication bus 40, as was described briefly above. Although FIG. 2 shows two rows of six equipment racks 28 supplied by two power distribution points 20, it should be noted that the number of rows, racks, and distribution points can vary depending on the requirements of the data center.

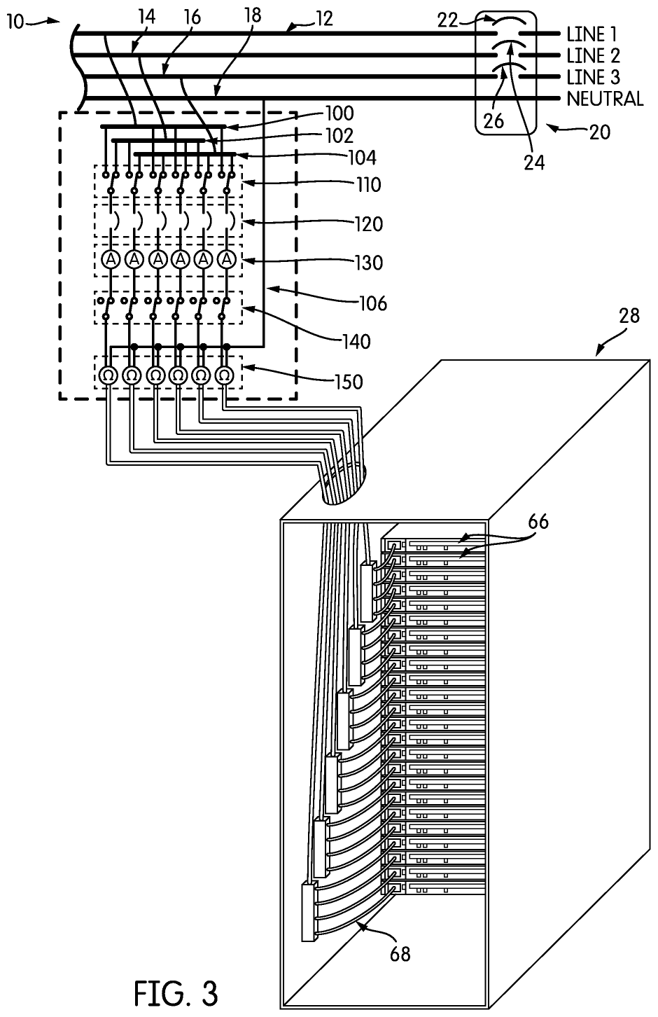

FIG. 3 is a schematic illustration similar to FIG. 1, including a more detailed diagram of a system module 30. Internal to the module 30 are distribution buses for the first phase, the second phase, and the third phase, which include a first phase line 100, a second phase line 102, and a third phase line 104. The Neutral wire of the three-phase wye system is shown at 106. Below the distribution buses are the phase selection relays or switches 110. The phase selection relays 110 allow one of two phases to be selected for delivery to the computational equipment 66. The two phases that are available for each delivery line to the computational equipment 66 are distributed evenly through the system module 30. More specifically, as can be seen in FIG. 3, the left most relay 110 is connected to phase lines 100 and 102, the next relay 110 is connected to phase lines 102, and 104, the next relay 110 over is connected to phase lines 104 and 100, etc. The precise phase lines 100, 102, 104 to which any particular relay 110 is connected is not critical so long as the relays 110 are arranged so that as a whole, there is an integral ratio of relays 110 to phases, for example two-to-one as shown. Increasing the ratio of relays 110 to phases to a three-to-one or four-to-one ratio increases the granularity, and improves the probability that a balanced condition can be obtained. It should be noted the centralized controller, described in more detail below, not only attempts to achieve balanced phase utilization at each rack, but also, and more advantageously, it attempts to achieve balanced phase utilization across all racks and the entire data center itself.

Although the symbol used in FIG. 3 is that of a relay, the switching device may be of a different type, for example, a rotary switch, a linear switch, a toggle switch, or a custom-design current-routing apparatus. The device used as a relay 110 should be capable of accepting the voltages that are typical during use and, as will be described below in more detail, it should be capable of automatic control. For example, in a North American installation, a relay 110 should be capable of handling 415 VAC and, more advantageously, rated to handle higher voltages as required by safety regulations and good electrical practice. A voltage rating of 480 VAC, for example, may be desirable in at least some embodiments.

As those of skill in the art will appreciate, in some cases, it may be possible or desirable to pair a switching apparatus that does not have automatic control capabilities with an apparatus to provide such control. For example, a conventional rotary switch may be paired with a stepper motor, or another type of electrically-controlled driving apparatus, to make a switch 110 suitable for use in the system module 30.

Connected to the outputs of the relays 110 are fault protection devices 120, typically circuit breakers or fuses of an appropriate size and capacity as required by safety regulations and good electrical practice. Ammeters 130 are used to monitor the current on each line. The system module 30 also includes circuit interruption relays or switches 140, which are used to interrupt the delivery of current to the computational equipment 66. Current interruption to the computational equipment 66 may be used to prevent the circuit breakers or fuses from tripping in the event of an overcurrent or short circuit condition. Additionally, the circuit interruption relays or switches 140 may be used to remove the power load of the computational equipment 66 from the circuit prior to the phase selection relays or switches 110 being activated. Removing the power load of the computational equipment 66 prior to actuating the phase selection relays or switches 110 may reduce arcing in the relays 110.

Ohmmeters 150 are used to detect if one or more pieces of the computational equipment 66 connected to that branch circuit are short circuited.

Although FIG. 3 shows the system module 30 with six branches or circuits of single phase power being delivered into the equipment rack 28, this is for illustration only, as the number of branches can vary depending on the application, and would typically increase as the total potential power requirement of the computational equipment increases.

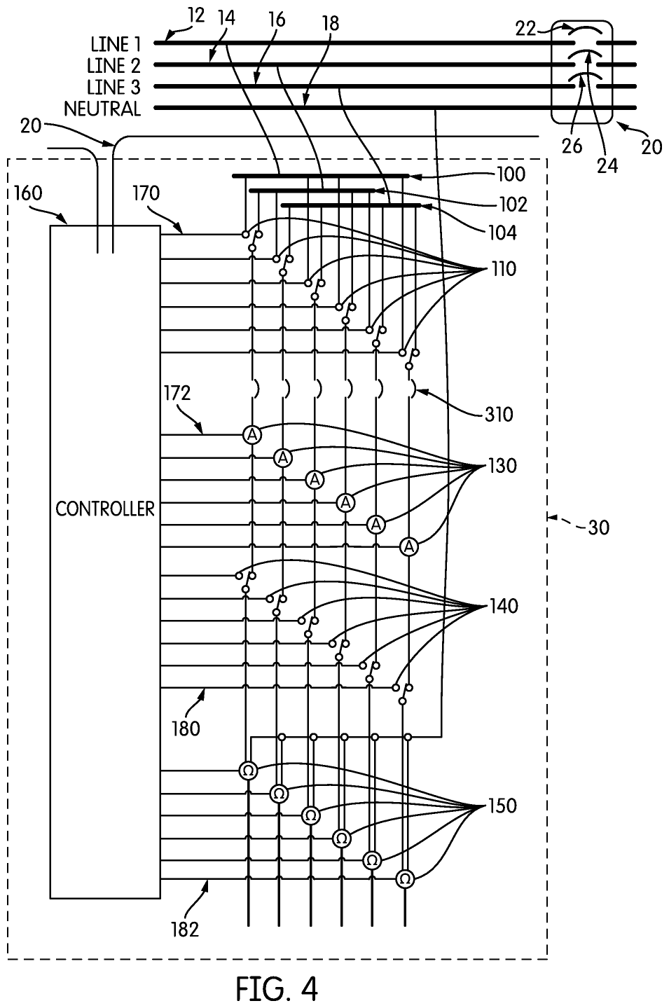

FIG. 4 is a more detailed version of FIG. 3, showing some of the interconnections of the system module with each of the monitoring and control components. The controller 160 contains the necessary circuitry to intelligently monitor and control the system, including but not limited to microprocessors, memory, communications systems, and related software. While the term “microprocessor” is used here for ease of description, any component capable of performing the functions ascribed to it in this description may be used, including, for example, microcontrollers, field-programmable gate arrays (FPGAs) and application-specific integrated circuits (ASICs).

The controller 160 controls the position of each phase selection relay or switch 110 by means of a control line 170. The controller 160 monitors the current on each circuit by means of connections 172 to the ammeters 130. The controller 160 controls the circuit interruption relays or switches 140 by means of control lines 180. The controller 160 reads the resistance at the output of the circuits as measured by the ohmmeters 150 by means of connecting lines 182.

Only the major components of the circuitry are shown for purposes of describing the operation. In addition, the connecting lines between the controller 160, relays or switches 110, 140, and meters 130, 150 are for purposes of demonstrating a functional connection. The nature of the interconnections may be analog, digital, electrical, optical or wireless, as an example.

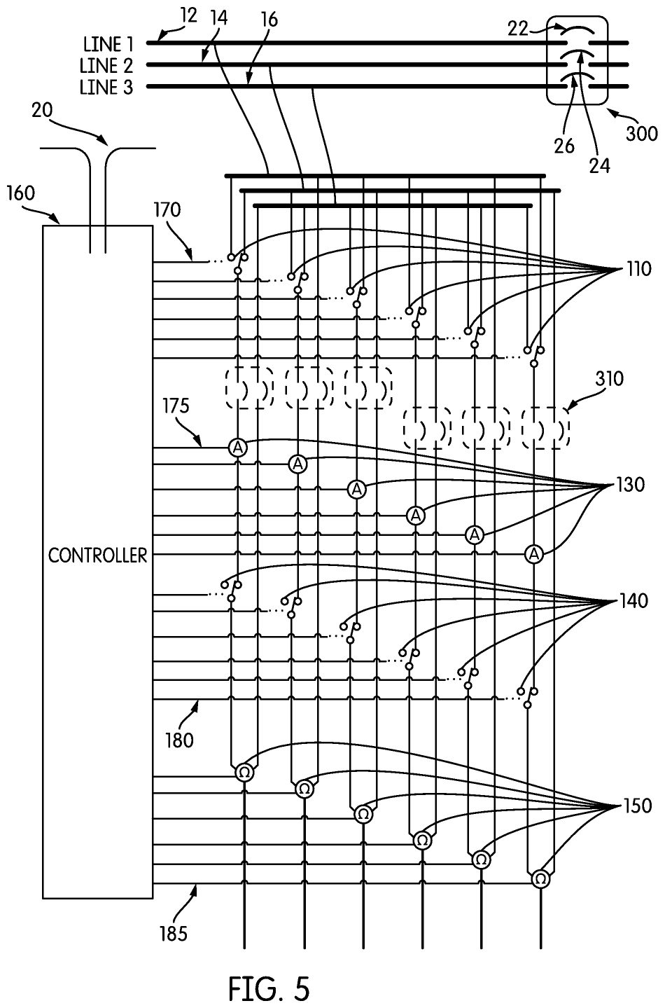

FIG. 5 illustrates an embodiment of a system module 300 configured for a three-phase delta power system. In a three-phase delta system, single phase power is delivered as phase pairs, and fault protection devices 310 are two-pole type. The configuration is otherwise essentially the same as the configuration of FIG. 4.

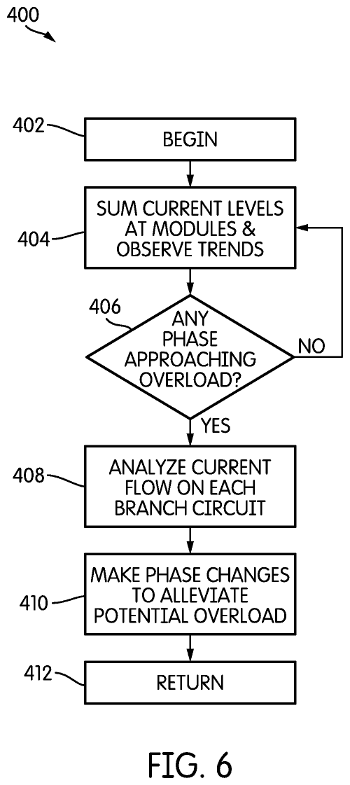

FIG. 6 is a flow diagram of a method, generally indicated at 400, for controlling the system modules 30 and managing the draw on any one phase of power in order to prevent overload. The software for performing this function may be contained in each of the system modules 30, or it may be contained in a master controller, which will be described below in more detail.

Method 400 begins at 402 and continues with task 404. In task 404, the controller 160 sums the current levels on each phase at each module 30. This would usually involve using the ammeter 130 on each phase-line to measure and calculate root mean square current. Typically, the current usage trend on each branch circuit is observed over some period of time, and when a measurement is taken in task 404, the trends are updated with the latest usage values.

In a typical embodiment, the controller 160 is pre programmed with a threshold that, if exceeded, is likely to cause the circuit protection devices 22, 24, 26 to trip. This threshold is directly related to the current rating of circuit protection devices 22, 24, 26, and may include information about the trip curves of those devices. For example, the controller 160 may be programmed with the maximum current values for the circuit protection devices 22, 24, 26 (i.e., the amperages at which the circuit protection devices 22, 24, 26 will trip), and sufficient information about the topology of the system or number of controllers 160 in operation for the controller 160 to have an idea of the current draw for its module 30 for each phase relative to the total current draw on each phase.

Method 400 continues with task 406, a decision task. If the current draw on any phase is at or has exceeded the threshold, or is imminently likely to reach and exceed the threshold as determined by trend data (task 406:YES), control passes to task 408. In determining whether the current draw is likely to exceed the threshold, the controller 160 may take into account the current consumption historical trend and project that, based on, e.g., a simple slope or time derivative of the curve, the current draw on a particular phase is likely to exceed the threshold within a particular time horizon if unchecked. The time horizon may vary from embodiment to embodiment and installation to installation but may be, e.g., 1 second, 2 seconds, 5 seconds, etc. If the current draw on any phase is not at the threshold and is unlikely to exceed the threshold within the time horizon (task 406:NO), control of method 400 returns to task 404 and the controller 160 continues to monitor.

In task 408, the controller 160 analyzes the current flow in each branch to find a phase with an acceptably low current load for phase switching purposes. This analysis may take into account both the present (i.e., instantaneous) current draw on the phases, as well as the trend. The controller 160 may determine whether, given the present current draw trend, the addition of current load on that phase would be likely to exceed the relevant threshold. Once a suitable phase is found to which to switch some or all of the current load, method 400 continues with task 410, and the appropriate phase changes are made by triggering the appropriate relays 140. Task 410 is further propagated to all connected controllers 160 that share the electrical service downstream of circuit protection devices 22, 24, 26. This may be accomplished by the election of one of the controllers 160 in the group to be the master controller, or by a master controller contained outside of the modules 30, which will be described below in more detail. The master controller analyzes all branches in the system which would typically number in the hundreds, and directs each module 30 to make the appropriate phase changes to alleviate potential overloads, effectively balancing the three phases within that group. Once any necessary changes are made to alleviate potential overload, method 400 returns in task 412. Assuming that there are no exceptions, method 400 is likely to run continuously or nearly continuously, immediately beginning again at task 402 after it returns at task 412.

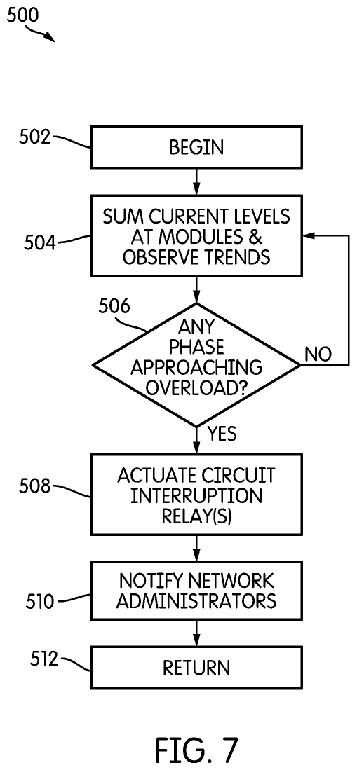

Method 400 is but one of several methods that may run in parallel on each controller 160 or on a master controller. As was described above, it is preferable to avoid tripping the main circuit protection devices 22, 24, 26, as these must often be manually reset by facility staff. Therefore, each system module 30 includes circuit interruption relays 140 that can be actuated automatically before current draws reach levels likely to trip the main circuit protection devices 22, 24, 26. Method 500 of FIG. 7 illustrates one particular method of using these circuit interruption relays 140.

Method 500 begins at 502 and continues with task 504. Tasks 504 and 506 are similar to or the same as tasks 404 and 406 of method 400, described above. If it is determined that any particular phase is approaching an overload (task 506:YES), method 500 continues with task 508 and the appropriate circuit interruption relay 140 is actuated. Method 500 continues with task 510 and a network administrator is notified before method 500 returns at task 512. If no phase is approaching an overload condition (task 506:NO), method 500 returns to task 504 and monitoring is continued.

Task 506 of method 500 may use its own current thresholds, distinct from the thresholds used in method 400, to determine when it is appropriate to actuate a circuit interruption relay 140. In some cases, method 500 may use the same thresholds as method 400.

While methods 400 and 500 may operate independently in parallel, in some cases, the controller 160 may trigger method 500 after certain tasks of method 400. However, in other cases, methods 400 and 500 may operate in a related or a dependent way. For example, if, in task 408, no suitable phase can be found that can carry the necessary current load, a controller 160 may begin method 500 and determine whether it is necessary to actuate one of the circuit interruption relays 140.

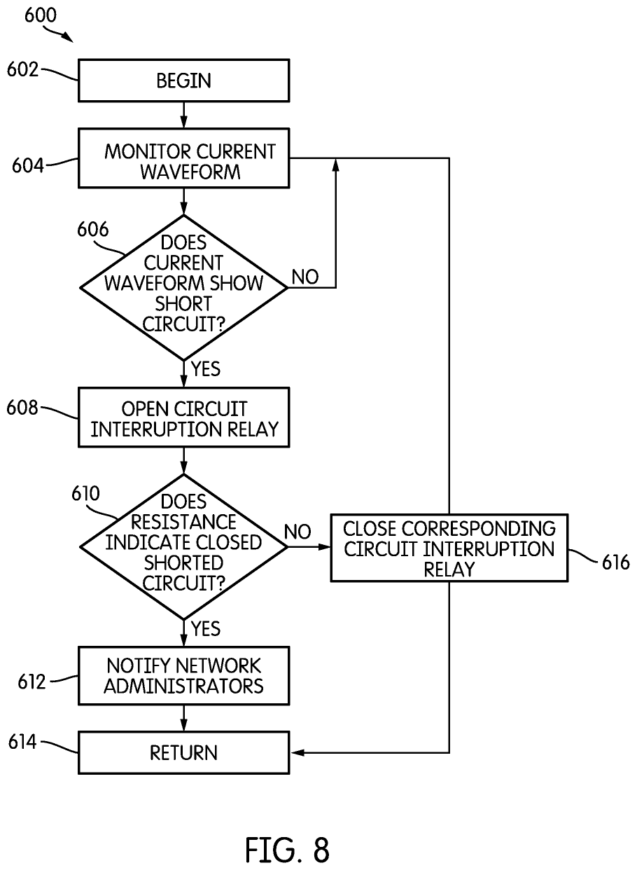

FIG. 8 is a flow diagram of a method, generally indicated at 600, for managing short circuit conditions on the electrical branch circuits in the equipment rack 28. As with the other methods 400, 500 described here, method 600 may be executed on a controller 160 or a master controller. Method 600 begins at 602 and continues with task 604. In task 604, the controller 160 or master controller monitors the current waveform. The current monitored may be the full digitized waveform at a speed and granularity necessary to identify a rapidly increasing short circuit condition.

Method 604 continues with task 606, a decision task. In task 606, if the current waveform of any phase or branch exhibits the profile of a short circuit (task 606:YES), method 600 continues with task 608. If the current waveform does not exhibit the profile of a short circuit (task 606:NO), method 600 returns to task 604 and monitoring continues.

In task 608 of method 600, the controller 160 opens the circuit interruption relay 140 that corresponds to the affected branch. Method 600 continues with task 610, another decision task. In task 610, the corresponding ohmmeter 150 is read. If the resistance in the branch indicates a closed, shorted circuit (task 610:YES), method 600 continues with task 612 and network administrators are notified before method 600 returns at task 614. If in task 610, the resistance in the branch circuit does not indicate a closed, shorted circuit (task 610:NO), method 600 continues with task 616 and the corresponding circuit interruption relay 140 is closed before method 600 continues with and terminates at task 614.

In essence, method 600 deals with temporary short circuits. If one is found, the corresponding circuit interruption relay is opened. However, method 600 also checks to see whether a short circuit has cleared itself. If so, the appropriate circuit interruption relay is closed again and operations continue as normal. If the short circuit does not clear itself, network administrators are notified.

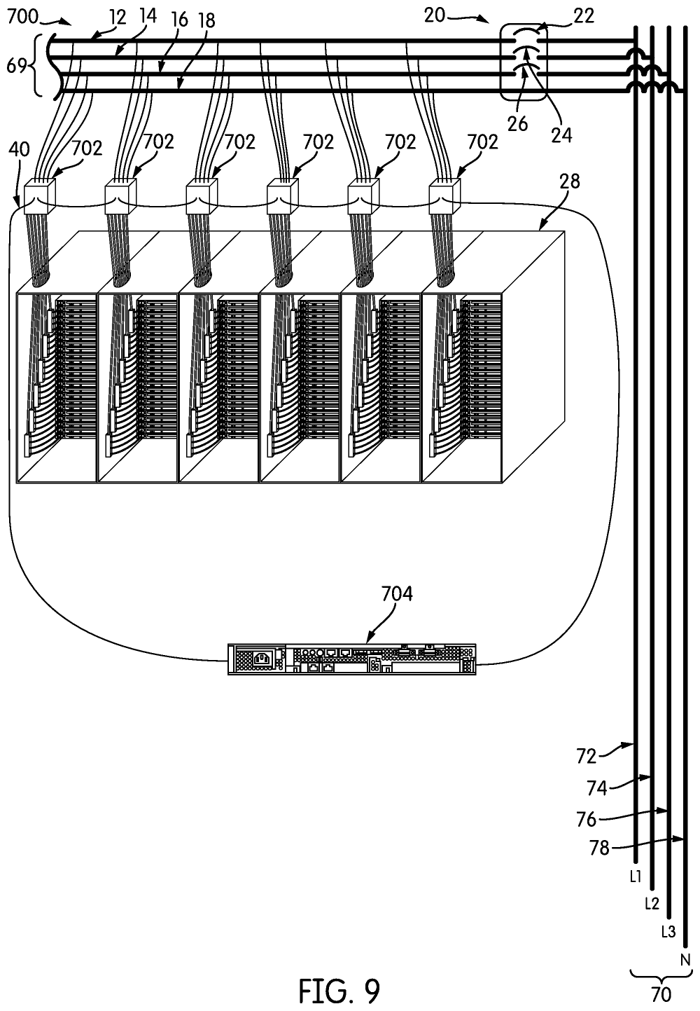

FIG. 9 is an illustration of a system, generally indicated at 700, according to another embodiment of the invention. System 700 is similar to the other systems described above. In particular, a number of system modules 702 provide the functions described above to a number of equipment racks 28. In system 700, a master controller 704 is employed to manage the system modules 702, and is connected to the system modules 702 through the data bus 40. In addition to controlling each system module 702, master controller 704 may also provide DC power to each system module 702 which would be beneficial in reducing the total cost of the system, as well as the size of each system module 702. The design of the master controller 704 may also include dual power inputs for redundancy, as well as dual power and communications inputs and outputs for redundancy. FIG. 9 shows a hard-wired wiring topology, in which the connections from the master controller 704 to the system modules 702 enter on each end of the chain of system modules 702. This provides the feature that if the cabling had a fault, such as a loose connection or break, communication to the system modules 100 would not be lost, as there is a secondary communication path. Although a hard-wired connection is shown for communication to the system modules 702, that communication may also occur via other protocols, such as radio frequency or optical technologies.

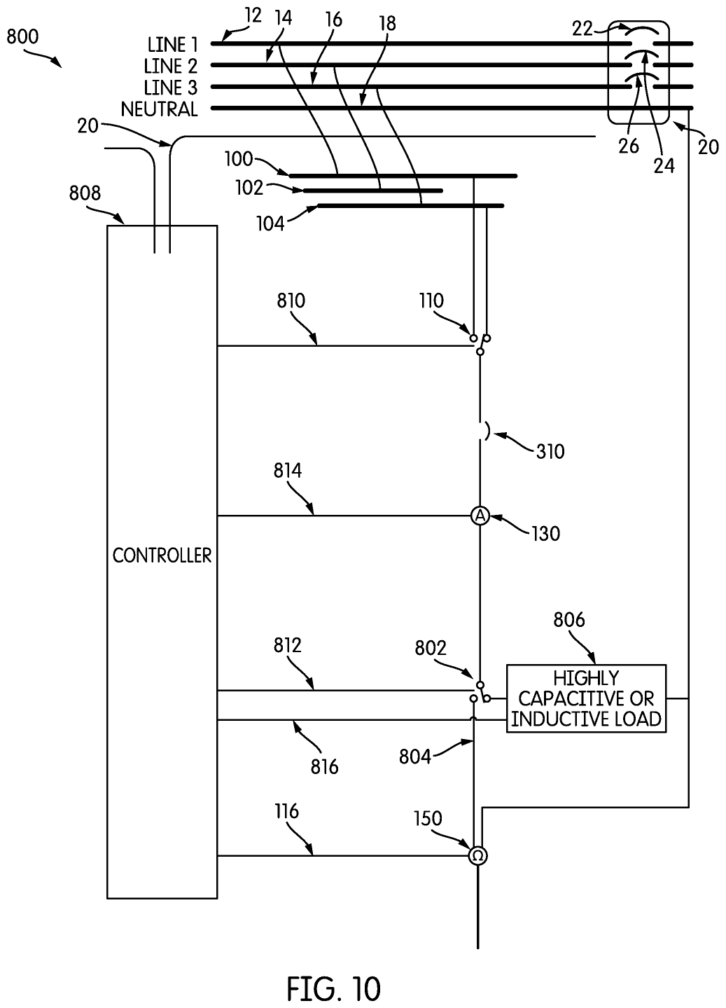

As those of skill in the art will appreciate, switching equipment from one phase to another may induce electrical arcing within the relay 110 that performs the switching operation. To reduce the likelihood of arcing, or to reduce its intensity, FIG. 10 is a circuit diagram of a module 800 illustrating the circuitry that allows one of the phases to be temporarily connected to a highly capacitive or inductive load for purposes of shifting that phase closer to the phase that the computational equipment will eventually be shifted to, thus reducing arcing within the phase selecting switch or relay.

Specifically, the module 800 has a controller 808 and a distribution bus with phase lines 100, 102, 104. As with many of the other embodiments described above, the configuration of the module 800 assumes a three-phase wye configuration, although as was set forth above, a three-phase delta configuration is also possible. The module 800 includes relays 110 that switch a load between two phases. Although only one relay 110 is shown in FIG. 10 for simplicity in illustration, as with the embodiments described above, any number of relays 110 may be used such that any load may be connected to any of the phase lines 100, 102, 104.

The module 800 has an output relay 802 in series with the phase-switching input relay 110. The output relay 802 switches its input between the regular load line 804 and a highly capacitive or inductive load 806. The highly inductive or capacitive load 806 may be variable in both load and phase, is connected to the controller 808 by its own control line 816, and would be controlled and selected by the controller 808 as appropriate to shift the waveform in the appropriate direction in order to minimize the potential for arcing in the relay. The highly capacitive or inductive load 806 will typically not be purely inductive or capacitive, but will have sufficient inductance or capacitance to shift the phase of the power meaningfully. For example, a phase shift of 45° is possible. As those of skill in the art will appreciate, the larger the phase shift, the less arcing is likely to occur in the phase-switching input relay 110.

The controller 808 is in communication with the phase-switching input relay 110 and the output relay 802 through respective control lines 810, 812, and also has a control/data line 814 to the ammeters 130 and a control/data line to the ohmmeters 150. Typically, when the controller 808 determines that a phase shift is necessary (e.g., using the methods described above), the characteristics of the highly inductive or capacitive load 806 would first be selected as appropriate, after which the output relay 802 would be switched to the highly capacitive or inductive load 806 before the phase-switching input relay 110 is switched between phase lines 100, 102, 104. Once the switching of the phase-switching input relay 110 is complete, the output relay 802 is actuated again to switch back to the regular load line. The operation may consume no more than a few tens of milliseconds.

While the invention has been described with respect to certain embodiments, the description is intended to be exemplary, rather than limiting. Modifications and changes may be made within the scope of the invention, which is defined by the appended claims.

1. A control module, comprising:
an internal power distribution bus having at least three phase lines;
a set of switching devices, each of the set of switching devices having two inputs, the two inputs of each of the set of switching devices connected to two different ones of the at least three phase lines, and each of the set of switching devices having a single power output, such that each of the set of switching devices is a two-to-one switching device;
a current measuring device arranged to measure current flow at the single power outputs of the set of switching devices; and
a controller connected to the set of switching devices and the current measuring device, the controller being constructed and arranged to measure a power load and to actuate the set of switching devices to balance the power load amongst the at least three phase lines.

2. The control module of claim 1, further comprising:
a second switching device between the single power outputs and the power load;
wherein the controller is further constructed and arranged to actuate the second switching device to disconnect the power load before actuating the set of switching devices, and to actuate the second switching device to reconnect the load after actuating the set of switching devices.

3. The control module of claim 2, further comprising:
a highly inductive or capacitive load connected to the second switching device, such that when the power load is disconnected, the single power outputs are connected to the highly inductive or capacitive load.

4. The control module of claim 1, further comprising:
a circuit interruption device connected between the single power outputs and a main load; and
a circuit continuity sensing device;
wherein the controller is further adapted to actuate the circuit interruption device if the circuit continuity sensing device senses a condition indicative of a short circuit.

5. The control module of claim 4, wherein the circuit continuity sensing device comprises an ohmmeter.

6. The control module of claim 1, wherein the distribution bus is a three-phase wye distribution bus.

7. The control module of claim 1, wherein the distribution bus is a three-phase delta distribution bus.

8. A method, comprising:
measuring a power load on each of three power phases in a power bus;
based on the measured power load on each of the three power phases and a defined threshold, automatically actuating one or more switching devices to balance the power loads of each of the three power phases, each of the one or more switching devices being a two-to-one switching device with two power inputs and a single power output, each of the two power inputs connected to a different phase line in the power bus.

9. The method of claim 8, further comprising switching to a null power load or to a highly capacitive or inductive power load prior to automatically actuating the one or more switching devices to balance the power loads.

10. The method of claim 9, further comprising switching from the null power load or the highly capacitive or inductive power load to the power loads after automatically actuating the one or more switching devices to balance the power loads.

11. The method of claim 8, further comprising detecting a short circuit condition.

12. The method of claim 8, further comprising automatically interrupting power in the event of an over-current condition prior to a fault protection device actuating.

13. A system, comprising:
at least two modules, each of the at least two modules being connected between a power distribution bus and a power load, and each of the at least two modules including
an internal power distribution bus having at least three phase lines, each of the at least three phase lines phase lines being connected to a corresponding phase line of the power distribution bus,
a set of switching devices, each of the set of switching devices having two inputs, the two inputs of each of the set of switching devices connected to two different ones of the at least three phase lines, and each of the set of switching devices having a single power output, such that each of the set of switching devices is a two-to-one switching device,
a current measuring device arranged to measure current flow at the at least one single power outputs of the set of switching devices, and
a controller connected to the set of switching devices and the current measuring device, the controller being adapted to measure the power load; and
a master controller in communication with the controllers of the at least two modules, the master controller being constructed and adapted to (1) take input from the controllers of the at least two modules as to the measured power loads, and (2) direct the controllers of the at least two modules to actuate the respective sets of switching devices to balance the measured power loads among the at least three phase lines.

14. The system of claim 13, each of the at least two modules further comprising:
a second switching device between the single power outputs and the power load;
wherein the controller is further constructed and arranged to actuate the second switching device to disconnect the power load before actuating the set of switching devices, and to actuate the second switching device to reconnect the load after actuating the set of switching devices.

15. The system of claim 14, each of the at least two modules further comprising:
a highly inductive or capacitive load connected to the second switching device, such that when the power load is disconnected, the single power outputs are connected to the highly inductive or capacitive load.

16. The system of claim 13, each of the at least two modules further comprising:
a circuit interruption device connected between the single power outputs and the power load; and
a circuit continuity sensing device;
wherein the controller is further adapted to actuate the circuit interruption device if the circuit continuity sensing device senses a condition indicative of a short circuit.

17. The system of claim 16, wherein the circuit continuity sensing device comprises an ohmmeter.

18. The system of claim 13, wherein the power distribution bus is a three-phase wye distribution bus.

19. The system of claim 13, wherein the power distribution bus is a three-phase delta distribution bus.
